(19) United States
(12) Patent Application Publication
(10) Pub. No.: US 2011/0089394 A1
(43) Pub. Date: Apr. 21, 2011

(54) SEMICONDUCTOR DEVICE

(75) Inventor: Tomoyasu KAKEGAWA, Tokyo (JP)

(73) Assignee: ELPIDA MEMORY, INC., Tokyo (JP)

(21) Appl. No.: 12/907,671

(22) Filed: Oct. 19, 2010

(30) Foreign Application Priority Data
Oct. 21, 2009 (JP) 2009-242529

(51) Int. Cl. H01L 45/00

(52) U.S. Cl. 257/4; 257/E45.001

(57) ABSTRACT

A semiconductor device includes a first insulating film over a semiconductor substrate. The first insulating film includes a first opening, a first electrode in the first opening, and a second insulating film over the first insulating film. The second insulating film includes a second opening that is positioned over the first electrode. The second opening includes a first conductive film. The first conductive film is electrically coupled to the first electrode. The first conductive film includes a top surface that is lower than a top surface of the second opening. The second opening includes a phase change material film. The phase change material film includes first and second portions. The first portion is surrounded by the first electrode and the first conductive film.

### BACKGROUND OF THE INVENTION

1. Field of the Invention

The present invention relates to a semiconductor device which is operated by using a phase change material.

Priority is claimed on Japanese Patent Application First Publication, No. 2009-242529, filed Oct. 21, 2009, the content of which is incorporated herein by reference.

2. Description of the Related Art

For a next generation non-volatile memory, a phase change memory such as PRAM: Phase Change Random Access Memory is actively being developed. It is discussed about related arts of PRAMs in Japanese Unexamined Patent Application, First Publication, Nos. 2008-085204, 2005-032855, 2005-525690, and 2005-159325. For example, Japanese Unexamined Patent Application, First Publication, No. 2008-085204, describes a semiconductor memory device which includes a heating part to be surrounded by a phase change film of a phase change element. Further, Japanese Unexamined Patent Application, First Publication, No. 2005-032855, describes a semiconductor device including a memory element that is surrounded by a resistance heating element, in which a conductive sidewall is formed on the entire side surface of a contact hole. Japanese Unexamined Patent Application, First Publication, No. 2005-525690, mentions a method including a formation step to electrically couple a phase change film to a base contact. Japanese Unexamined Patent Application, First Publication, No. 2005-159325, describes that a phase change memory element includes a phase change material pattern which contacts the side surface of an electrode hole of a heating electrode.

A phase change memory device is a memory that includes a phase change element. The phase change element includes a phase change material and a heater electrode (a heating electrode) which is provided to contact to the phase change material, in which the phase change material becomes a low resistivity in a crystalline state and becomes a higher resistivity in amorphous state. Joule heat is generated when a current flows through the heater electrode, and the heat is used to change the phase of the phase change material either from an amorphous state to a crystalline state or from a crystalline state to an amorphous state so that the resistivity of the phase change material is changed.

In order to perform the phase transition of the phase change material from the crystalline state to the amorphous state, i.e., from a low resistivity to a high resistivity, a relatively large current (a reset current) is driven through the heater electrode so that the phase change material is melted, then the current is turned off for rapidly cooling the phase change material (reset operation).

Further, when performing the phase transition of the phase change material from the amorphous state to the crystalline state, i.e., from a high resistivity to a low resistivity, a relatively small current (a set current) is driven through the heater electrode so that the phase change material is held at its crystallization temperature which is below the melting point of the phase change material.

In general, there is a disadvantage for a phase change element which it requires high power consumption because the operation current, such as the reset current and the set current, is large. To reduce the power consumption of the phase change element, it is required that an effective volume which a state of the crystal of the phase change material is actually changed (phase change region) is reduced as much as possible, and further it is required to reduce a contact resistance between the phase change material and a heater electrode.

Japanese Unexamined Patent Application, First Publication, No. 2008-085204, it describes that a phase change material is filled in a contact hole with a small diameter, in which a heater electrode is formed at the bottom of the contact hole, so that a volume of the phase change region is reduced. This structure, however, would reduce an area of the contact (contact area) between the phase material and the heater electrode with decrease in a diameter of the contact hole, so that its contact resistance (interface resistance) becomes high. High contact resistance makes it difficult to provide enough operation current (especially, reset current) for changing the state of the crystal of the phase change material. Further, as the design size of a semiconductor device is reduced, transistors of memory cells become smaller. This brings a lower current drive capability (on current) for the phase change element, thus a deficiency of the current drive capability becomes a more serious issue.

Japanese Unexamined Patent Application, First Publication, No. 2005-032855 describes a structure of a phase change element in which a resistance heating element (heating electrode) is formed on the entire side surface of a contact hole where a phase change material is filled in. It is mentioned that this structure can enlarge the area of the contact between the phase change material and the heating electrode, so that its contact resistance is reduced. However, the structure of Japanese Unexamined Patent Application, First Publication, No. 2005-032855 needs to heat another area in addition to the phase change region, and thus the heating efficiency of the phase change material is reduced.

In general, it is required for a semiconductor device with a phase change material and a manufacturing method thereof to reduce the operation current without reducing the heating efficiency of the phase change material.

### SUMMARY

In one embodiment, a semiconductor device may be include, but not limited to, a first insulating film over a semiconductor substrate, a first electrode in the first opening, a second insulating film on the first insulating film, a first conductive film in the second opening, and a phase change material film in the second opening. The first insulating film may have a first opening. The second insulating film may have a second opening that exposes a top surface of the first electrode. The first conductive film may be electrically coupled to the first electrode. The first conductive film may be connected to the first electrode. The first conductive film may have a top surface that is lower than a top surface of the second insulating film. The phase change material film may include first and second portions in the second opening, the first portion being disposed on the top surface of the first electrode and a side surface of the first conductive film.

In another embodiment, a semiconductor device may include, but not limited to, an insulating film having an opening, a conductive layer in the opening, and a phase change material film in the opening. The conductive film may have a trench portion (non-flat surface). The trench portion may have a top surface that is lower than a top surface of the insulating film. The phase change material film may include first and second portions. The first portion may contact the top surface of the trench portion of the conductive layer. The first portion may be surrounded by a side surface of the trench portion. The first portion may be positioned below the top surface of the trench portion. The second portion may be positioned above the top surface of the trench portion.

In still another embodiment, a semiconductor device may include, but not limited to, a first insulating film over a semiconductor substrate, a first electrode in the first opening, a second insulating film over the first insulating film, a conductive film in the second opening, a current confining film adjacent to the conductive film, and a phase change material film in the second opening. The first insulating film may have a first opening. The second insulating film may have a second opening that is positioned over a top surface of the first electrode. The conductive film may be electrically coupled to the first electrode. The conductive film may have a top surface that is lower than a top surface of the second opening. The current confining film may confine an electrical current in the conductive film. The phase change material film may contact the first electrode. The phase change material film may be surrounded by the conductive film and the current confining film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a diagram illustrating the cross-section of a semiconductor device in accordance with a first preferred embodiment of the present invention;

FIG. 2A is a diagram illustrating the cross-section of the semiconductor device in accordance with the first preferred embodiment of the present invention;

FIG. 2B is a diagram illustrating the cross-section of another semiconductor device for comparison with the semiconductor device of FIG. 2A;

FIG. 3 is a diagram illustrating the cross-section of the semiconductor device at a process step for showing the manufacturing method of the semiconductor device in accordance with the first preferred embodiment of the present invention;

FIG. 4 is a diagram illustrating the cross-section of the semiconductor device at a process step for showing the manufacturing method of the semiconductor device in accordance with the first preferred embodiment of the present invention;

FIG. 5 is a diagram illustrating the cross-section of the semiconductor device at a process step for showing the manufacturing method of the semiconductor device in accordance with the first preferred embodiment of the present invention;

FIG. 6 is a diagram illustrating the cross-section of the semiconductor device at a process step for showing the manufacturing method of the semiconductor device in accordance with the first preferred embodiment of the present invention;

FIG. 7 is a diagram illustrating the cross-section of the semiconductor device at a process step for showing the manufacturing method of the semiconductor device in accordance with the first preferred embodiment of the present invention;

FIG. 8 is a diagram illustrating the cross-section of the semiconductor device at a process step for showing the manufacturing method of the semiconductor device in accordance with the first preferred embodiment of the present invention;

FIG. 9 is a diagram illustrating the cross-section of another semiconductor device in accordance with a second preferred embodiment of the present invention;

FIG. 10 is a diagram illustrating the cross-section of the semiconductor device of FIG. 9 at a process step for showing the manufacturing method of the semiconductor device in accordance with the second preferred embodiment of the present invention;

FIG. 11 is a diagram illustrating the cross-section of another semiconductor device in accordance with a third preferred embodiment of the present invention; and

FIG. 12 is a diagram illustrating the cross-section of the semiconductor device of FIG. 11 at a process step for showing the manufacturing method of the semiconductor device in accordance with the third preferred embodiment of the present invention.

### DETAILED DESCRIPTION OF THE PREFERRED EMBODIMENTS

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may be include, but not limited to, a first insulating film over a semiconductor substrate, a first electrode in the first opening, a second insulating film over the first insulating film, a first conductive film in the second opening, and a phase change material film in the second opening. The first insulating film may have a first opening. The second insulating film may have a second opening that is positioned over the first electrode. The first conductive film may be electrically coupled to the first electrode. The first conductive film may have a top surface that is lower than a top surface of the second opening. The phase change material film may include first and second portions, the first portion being surrounded by the first electrode and the first conductive film.

In some cases, the first portion of the phase change material film may be located under the second portion of the phase change material film in the second opening,

In some cases, the first conductive film may include, but not limited to, a conductive sidewall on a side surface of the second opening. The conductive sidewall may surround the first portion of the phase change material film.

In some cases, the semiconductor device may include, but not limited to, an insulating sidewall on the side surface of the second opening. The insulating sidewall may be positioned on a top surface of the conductive sidewall.

In some cases, the phase change material film may include a layered portion that extends on the second insulating film. The second portion may be disposed between the layered portion and the first portion of the phase change material film.

In some cases, the semiconductor device may include, but not limited to, a second electrode. The second electrode may be disposed on a top surface of the layered portion of the phase change material film.

In some cases, the second portion may be surrounded by the insulating sidewall. The first portion may include a phase change region to vary in resistance by a heat generated by the first electrode.

In some cases, the first portion may have a first dimension in a first direction parallel to an upper surface of the insulating film. The first dimension may be equal to or less than 1.2 times of a second dimension of the first portion. The second dimension may be defined in a second direction vertical to the first direction.

In some cases, the second opening may have a third dimension in the second direction and a fourth dimension in the first direction. The third dimension may be equal to or greater than the fourth dimension.

In some cases, a material of the first electrode may include the same material as that of the first conductive film.

In some cases, the first conductive film may include, but not limited to, at least one of a metal or an alloy which are lower in resistivity than the phase change material film in amorphous state.

In some cases, the first conductive film may include, but limited to, at least one of tungsten, titanium, tantalum, titanium nitride, tantalum silicide nitride and titanium silicide nitride.

In some cases, the semiconductor device may include, but not limited to, a switching element coupled to the first electrode.

In another embodiment, a semiconductor device may include, but not limited to, an insulating film having an opening, a conductive film in the opening, and a phase change material film in the opening. The conductive film may have a trench portion (non-flat surface). The trench portion may have a top surface that is lower than a top surface of the insulating film. The phase change material film may include first and second portions. The first portion may contact the trench portion. The first portion may be surrounded by the trench portion. The first portion may be positioned below the top surface of the trench portion. The second portion may be positioned above the top surface of the trench portion.

In some cases, the conductive layer may include, but not limited to, an electrode film in a lower portion of the opening; and a conductive sidewall on a side surface of the opening. The conductive sidewall may be disposed on an upper surface of the electrode film. The trench portion may include the conductive sidewall and the upper surface of the electrode film. The first portion of the phase change material film may be surrounded by the conductive sidewall.

In some cases, the first portion of the phase change material film may include, but not limited to, a first dimension in a first direction parallel to an upper surface of the insulating film. The first dimension may be equal to or less than 1.2 times of a second dimension of the first portion. The second dimension may be defined in a second direction vertical to the first direction.

In some cases, the semiconductor device may include, but not limited to, an insulating sidewall on the side surface of the opening. The insulating sidewall may be positioned over the conductive sidewall. The insulating sidewall may surround the second portion of the phase change material film.

In some cases, the trench portion may have a bottom surface which has a bottom level. A difference between the top surface and the bottom surface of the trench portion may be equal to or less than 1.2 times of the horizontal dimension of the opening. The horizontal dimension may be defined in the second direction.

Further, embodiments of the present invention may include methods for manufacturing the semiconductor device. The methods for manufacturing the semiconductor device will be described below in accordance with a preferred embodiment of the present invention.

In one of examples, the method for manufacturing the semiconductor device may include, but not limited to, the following processes. A heater electrode for a first interlayer insulating film is formed after forming the first interlayer insulating film on a semiconductor substrate. A hole for a second interlayer insulating film is formed to expose the top surface of the heater electrode after forming the second interlayer insulating film to cover the first interlayer insulating film. A conductive sidewall film which covers the lower side surface of the hole is formed by performing a first etch-back process for the conductive film after forming the conductive film which cover the second interlayer insulating film and the inside surface of the hole. The insulating film which covers the upper side surface of the hole is formed by performing a second etch-back process for the insulating film after forming the insulating film which covers the second interlayer insulating film and the surface of the conductive sidewall film in the hole. The phase change material film is formed, which fills the hole through the insulating film and the conductive film and which covers the second interlayer insulating film. The upper electrode is formed, which covers the phase change material film.

In some cases, the forming of the conductive sidewall film may include forming a trench portion for the heater electrode after etching the heater electrode while the etch-back process is performed for the conductive film after the conductive film having the same material as that of the heater electrode is formed. The conductive film has the same material as that of the heater electrode.

In some cases, the method may include thinning the second interlayer insulating film by polishing the second interlayer insulating film with CMP method after forming the phase change material film and before forming the upper electrode.

Hereinafter, embodiments of the present invention will be described in detail with reference to the drawings.

The following drawings illustrate the embodiments of the present invention. The size, thickness or dimension of each portion shown in the drawings may be different from a dimension relationship of an actual semiconductor device.

### First Embodiment

A semiconductor device will be described below in accordance with a first preferred embodiment of the present invention.

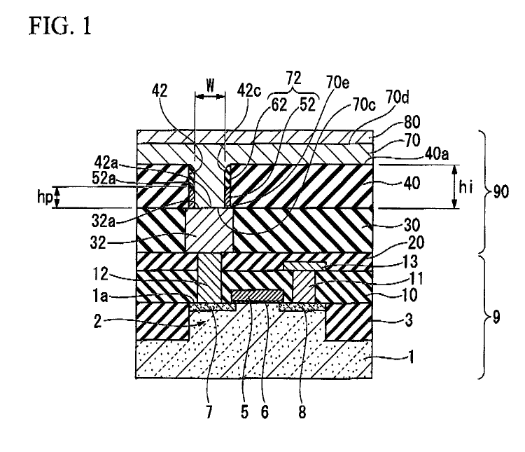

FIG. 1 is a diagram illustrating the cross-section of a semiconductor device in accordance with a first preferred embodiment of the present invention, where the cross-section shows a memory cell. Further, numbers indicating a film thickness or the like are used in figures and descriptions below for describing examples, and thus the present invention is not limited by those of numbers and it is possible to modify those of numbers.

As is seen in FIG. 1, the semiconductor device is a phase change memory in accordance with the first preferred embodiment. The phase change memory includes a switching element 9 and a phase change element 90 formed on a semiconductor substrate 1. In this case, the switching element 9 is an element that selects addresses on the memory cell.

Device isolation regions 3 are formed in a plane 1 a of the semiconductor substrate 1, and a section isolated by the device isolation regions 3 corresponds to an active region 2. The semiconductor substrate 1 is made from a first conductivity (P-type) silicon or the like.

The active region 2 includes the switching element 9 which is a Metal-Oxide-Semiconductor transistor (MOS transistor) having a gate electrode 5, a gate insulating film 6, and source-drain regions 7 and 8 having a second conductivity type (N-type). The source-drain regions 7 and 8 are arranged to sandwich the gate electrode 5 between the regions 7 and 8.

A third interlayer insulating film 10 is formed to cover the gate electrode 5. The third interlayer insulating film 10 may be formed of silicon oxide (SiO₂), silicon nitride (Si₃N₄) or the like. The third interlayer insulating film 10 includes a first contact plug 11 which is coupled to the source-drain region 8. A power source line 13 is formed over the third interlayer insulating film 10. The power source line 13 is coupled to the first contact plug 11. The first contact plug 11 can be formed with tungsten, impurity doped polysilicon or the like. The power source line 13 can be formed of tungsten or the like.

A fourth interlayer insulating film 20 is formed to cover the power source line 13 and the third interlayer insulating film 10. The fourth interlayer insulating film 20 may be formed of silicon oxide, silicon nitride (Si₃N₄) or the like.

A second contact plug 12 is formed, which penetrates the fourth interlayer insulating film 20 and the third interlayer insulating film 10. The second contact plug 12 is coupled to the source-drain region 7. The second contact plug 12 can be formed of tungsten, impurity doped polysilicon or the like.

A phase change element 90 is formed over the switching element 9. The phase change element 90 includes a heater electrode 32 which further includes a lower electrode part and a heater electrode part, a phase change material film 70, and an upper electrode 80. A first interlayer insulating film 30 is formed to cover the fourth interlayer insulating film 20. The first interlayer insulating film 30 may be made of silicon oxide (SiO₂), silicon nitride (Si₃N₄) or the like.

In the first interlayer insulating film 30, a through hole is formed to expose the top surface of the second contact plug 12. The through hole is filled with the heater electrode 32. The heater electrode 32 is electrically coupled to the source-drain region 7 of the MOS transistor via the second contact plug 12. The heater electrode 32 can be formed of tungsten or the like.

A second interlayer insulating film 40 is formed to cover the first interlayer insulating film 30. The second interlayer insulating film 40 may be made of silicon oxide, silicon nitride (Si₃N₄) or the like. A film thickness hi of the second interlayer insulating film 40 may be, for example, about 100 nm. A hole 42 is formed through the second interlayer insulating film 40 so as to expose a top surface 32a of the heater electrode 32. The diameter of the hole 42 may be, for example, about 100 nm.

A double layer sidewall 72 having a double layer structure is formed on the side surface 42c of the hole 42. The double layer sidewall 72 includes a conductive sidewall film 52 and an insulating sidewall film 62. The conductive sidewall film 52 is formed to cover on a lower part of the side surface 42c of the hole 42. The insulating sidewall film 62 is formed to cover on an upper part of the side surface 42c of the hole 42. In the hole 42, the conductive sidewall film 52 and the insulating sidewall film 62 are provided so as to surround a side surface 70e of the phase change material film 70.

A material can be used for the conductive sidewall film 52, as long as a resistance of the material is lower than that of the phase change material film 70 of amorphous state. For example, the material of conductive sidewall film 52 may be titanium nitride (TiN), tungsten (W), titanium (Ti), tantalum (Ta), tantalum silicide nitride (TaSiN), titanium silicide nitride (TiSiN) or the like.

Further, the insulating sidewall film 62 may be, for example, an insulating film formed with silicon nitride, silicon oxide or the like.

The conductive sidewall film 52 and the insulating sidewall film 62 have almost the same thickness. The thickness may be, for example, about between 10 nm and 15 nm.

At a bottom 42a of the hole 42, the width W (hereafter, opening width W or opening dimension W) is a part where the conductive sidewall film 52 does not exist. The opening width W corresponds to the dimension (or diameter) of a plane 70c at which the heater electrode 32 contacts the phase change material film 70. The opening width W may be, for example, about 70 nm.

The conductive sidewall film 52 has a height (or dimension) hp which is about 50 nm, and the insulating sidewall film 62 has a height (or dimension) hd which is about 50 nm. The top end of the insulating sidewall film 62 is almost the same level as the top surface of the second interlayer insulating film 40.

The phase change material film 70 is formed to fill in the hole 42 with covering the top surface 40a of the second interlayer insulating film

For the phase change material film 70, chalcogenide materials can be used. The chalcogenide related materials may be alloys or compound materials which includes at least one element selected from germanium (Ge), antimony (Sb), tellurium (Te), indium (In), and selenium (Se). More specifically, the materials may be binary compounds such as GaSb, InSb, InSe, Sb₂Te₃ and GeTe, ternary compounds such as Ge₂Sb₂Te₅, InSbTe, GaSeTe, SnSb₂Te₄ and InSbGe, and quaternary compounds such as AgInSbTe, (GeSn)SbTe, GeSb(SeTe), Te₈₁Ge₁₅Sb₂S₂, or the like.

A thickness of the phase change material film 70 may be, for example, about 60 nm.

As shown in FIG. 1, the upper electrode 80 is formed to cover the top surface 70d of the phase change material film 70. The upper electrode 80 may be formed of titanium nitride, or a stacking film of titanium and titanium nitride or the like. A thickness of the upper electrode 80 may be, for example, about 50 nm. The upper electrode 80 and the phase change material film 70 can be used for bit lines by patterning them to form wirings extending in a predetermined direction.

As described above, the semiconductor device in accordance with a first preferred embodiment of the present invention is manufactured.

Further, an insulating film covering the upper electrode 80 and other upper electrode wirings may be formed over the present structure.

As is shown in FIG. 1, for the semiconductor device in accordance with a first preferred embodiment, a planer MOS transistor is used as the switching element 9. However, the switching element 9 is not limited to the planer type. Other type of transistors may be used, such as a transistor with a grooved gate and a vertical transistor with a pillar shape channel region in which a gate electrode is formed at the side of the pillar shape channel region.

Further, a diode element may be used as the switching element 9 instead of the MOS transistor. When the diode element is used, a cross-point type memory cell can be formed.

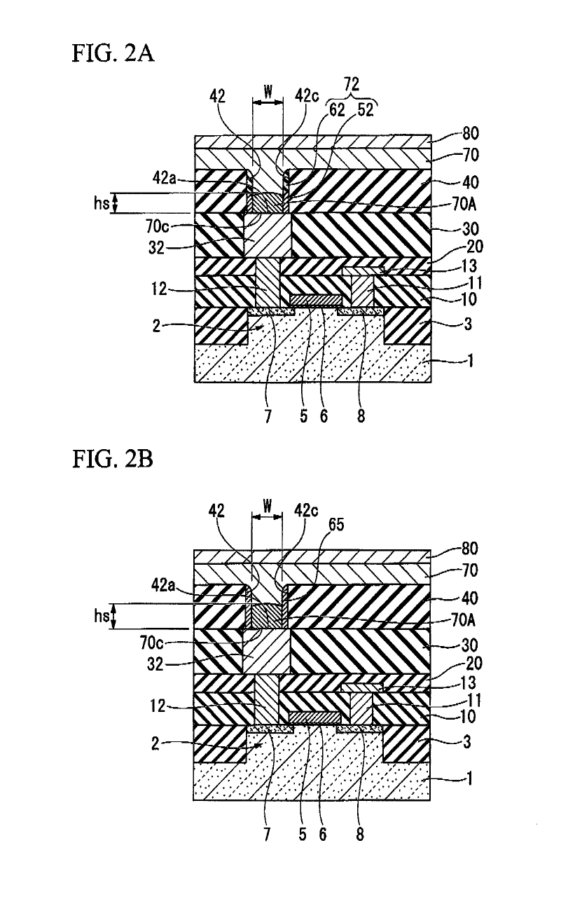

FIG. 2A and FIG. 2B show the semiconductor device of the first preferred embodiment and a semiconductor device as a comparative example. FIG. 2A is a diagram illustrating the cross-section of the semiconductor device in accordance with the first preferred embodiment of the present invention. FIG. 2B is a diagram illustrating the cross-section of the semiconductor device as a comparative example.

In FIG. 2A, the semiconductor device includes the double layer sidewall 72, while the reference semiconductor device in FIG. 2B includes a single layer sidewall 65 formed with a dielectric material. These two semiconductor devices include identical structures except for the difference between the double layer sidewall 72 and the single layer sidewall 65.

For each of the semiconductor devices of FIGS. 2A and 2B, the phase change material film 70 is filled in the hole 42 of the semiconductor devices of FIGS. 2A and 2B through the double layer sidewall 72 and the single layer sidewall 65, respectively. In both cases, the phase change material film 70 is electrically coupled to the heater electrode 32 at a bottom surface 42a of the hole 42, and the top surface of the phase change material film 70 is electrically coupled to the upper electrode 80. When a current is driven through the upper electrode 80 and the heater electrode 32, a region 70A of the phase change material film 70 (hereafter, phase change region 70A) located at a side of the heater electrode 32 in the hole 42 is heated up, and then a phase of the phase change region 70A is changed, resulting a change in the resistance of the phase change material at the phase change region 70A.

A width (or dimension) of the phase change region 70A is defined by the width (or dimension) of a region which is not covered with the double layer sidewall 72 of the hole 42 or the width (or dimension) of a region which is not covered with the single layer sidewall 65 of the hole 42. In other words, the width is dependent on the opening diameter (or dimension) W The height (or dimension) hs of the phase change region 70A becomes almost similar to the opening diameter W.

The double layer sidewall 72 or the single layer sidewall 65 is formed in the hole 42 of each of the semiconductor devices of FIG. 2A and FIG. 2B, so that the opening diameter W can be formed to be smaller than that formed by a lithography step which determines an original diameter of the hole 42. Thereby, a volume of the phase change region 70A can be reduced, so that an operation current required to cause a phase change of the phase change material at the phase change region 70A can be decreased. Therefore, the resistance of the phase change material at the phase change region 70A can be changed with less operation current.

For the semiconductor device of FIG. 2B, if the single layer sidewall 65 is formed to be higher (or greater) than the height (or dimension) hs of the phase change region 70A, the upper part of the single layer sidewall 65 does not contact the phase change region 70A, so the upper part of the single layer sidewall 65 normally contacts with the phase change material film 70 which has a lower resistance because of a crystalline state (or phase). In this case, the operation current is used to flow through the phase change material film 70 instead of flowing through the phase change material at the phase change region 70A, so that a heating efficiency for changing the phase of the phase change material at the phase change region 70A is decreased.

On the other hand, for the semiconductor of FIG. 2A according to the first embodiment, the double layer sidewall 72 including the conductive sidewall film 52 and the insulating sidewall film 62 is formed on the side surface 42c of the hole 42. As the conductive sidewall film 52 allows a current flow through the heater electrode 32, the conductive sidewall film 52 can be used as a heater electrode, while the insulating sidewall film 62 does not function as a heater electrode because it is formed from an insulating material. Thus, when the height (or dimension) hp (indicated in FIG. 1) of the conductive sidewall film 52 is similar to the height (or dimension) hs of the phase change region 70A, it can be avoided that the conductive sidewall film 52 contacts the phase change material film 70 having a low resistance in crystalline state. This allows the conductive sidewall film 52 to contact the phase change region 70A with a very small contact area, which results in heating only the phase change region 70A. Thereby, the semiconductor device of FIG. 2A can reduce the operation current to change a phase of the phase change material at the phase change region 70A compared to the semiconductor device of FIG. 2B. The resistance of the phase change material can be changed with lower operation current. It can also improve the heating efficiency for changing the phase of the phase change material.

It is preferable that the height hp (or dimension hp) of the conductive sidewall film 52 is equal to or less than the height ha (or dimension hs) of the phase change region 70A of the phase change material film 70. It is also preferable that the height hp of the conductive sidewall film 52 is equal to or less than the opening diameter W (or opening dimension W) of the plane 70c that contacts the heater electrode 32, because the height (or dimension) hs of the phase change region 70A is almost the same as the opening diameter W.

Specifically, it is preferable that the height hp of the conductive sidewall film 52 is smaller than 1.2 times of the opening diameter W. Thereby, the conductive sidewall film 52 does not contact the phase change material film 70 which is a low resistance (crystalline state), and it is possible that the conductive sidewall film 52 contacts the phase change region 70A of the phase change material film 70 at a very small contact area. Thus, only the phase change region 70A can be heated up. This makes it possible to improve the heating coefficient for the phase change material without unnecessary consumption of current.

Further, it is preferable that the height hp of the conductive sidewall film 52 is smaller than 1.2 times of the opening diameter W and larger than 0.7 times of the opening diameter W. Thereby, it is possible that only the phase change region 70A is heated up and the contact area between the phase change material film 70 and the heater electrode 32 can be optimized, so that it improves the heating coefficient for the phase change material without consuming additional current.

Now, the following will describe a manufacturing method of the semiconductor device in accordance with a preferred embodiment of the present invention.

The manufacturing method of the semiconductor according to the preferred embodiment includes forming the heater electrode 32, forming the hole 42, forming a conductive sidewall film 52, forming the insulating sidewall film 62, forming the phase change material film 70, and forming the upper electrode 80.

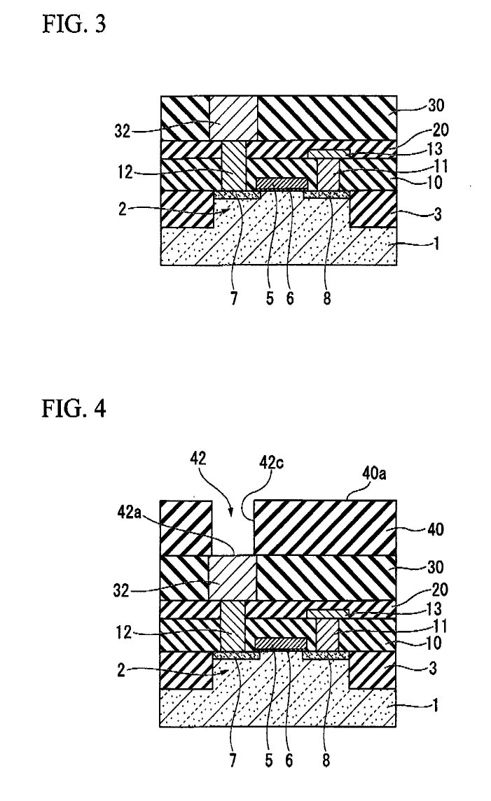

FIGS. 3 through 8 illustrate the manufacturing method of the semiconductor device in accordance with one preferred embodiment of the present invention. The semiconductor device shown in FIG. 1 is manufactured through the process shown in these figures.

### [First Process Step]

FIG. 3 is a diagram illustrating the cross-section of the semiconductor device at a process step for showing the manufacturing method of the semiconductor device in accordance with a preferred embodiment of the present invention. FIG. 3 shows a process step in which the heater electrode 32 is formed.

Device isolation regions 3 are formed with a shallow trench isolation method (STI) at first, and a region isolated by the isolation regions 3 is used as an active region 2.

Next, the MOS transistor is formed as the switching element 9 in the active region 2. The MOS transistor includes the gate electrode 5, the gate insulating film 6, and the source-drain regions 7 and 8 having the second conductive type (N-type). The source-drain regions 7 and 8 are arranged to sandwich the gate electrode 5 between the regions 7 and 8.

Further, the third interlayer insulating film 10 may be formed of silicon oxide (SiO₂), silicon nitride (Si₃N₄) or the like to cover the top of the MOS transistor.

An opening for the first contact plug 11 is formed in the third interlayer insulating film 10 to expose the source-drain region 8 of the MOS transistor. A conductive material is filled in the opening for forming the first contact plug 11 which is electrically coupled to the source-drain region 8, in which the conductive material may be tungsten (W), impurity doped polysilicon or the like. The power source line 13 is formed over the third interlayer insulating film 10 so that the power source line 13 is electrically coupled to the first contact plug 11.

The fourth interlayer insulating film 20 is formed to cover the power source line 13 and the third interlayer insulating film 10. The fourth interlayer insulating film 20 can be formed of silicon oxide, silicon nitride or the like.

An opening for the second contact plug 12 is formed to penetrate the fourth interlayer insulating film 20 and the third interlayer insulating film 10 so that the opening exposes the source-drain region 7. The conductive material is filled in the opening through the fourth interlayer insulating film 20 and the third interlayer insulating film 10 so that the second contact plug 12 is formed. The second contact plug 12 is electrically coupled to the source-drain region 7. The conductive material may be tungsten, impurity doped polysilicon or the like.

The first interlayer insulating film 30 is formed to cover the fourth interlayer insulating film 20. The first interlayer insulating film 30 may be made of silicon oxide, silicon nitride (Si₃N₄) or the like.

An opening for the heater electrode 32 is formed in the first interlayer insulating film 30 to expose the top surface of the second contact plug 12. The material of the heater electrode 32 is formed to fill the opening for the heater electrode 32 and cover the first interlayer insulating film 30 by using chemical vapor deposition (CVD) method. The material for the heater electrode 32 may be tungsten or the like.

The material covering the first interlayer insulating film 30 is removed by chemical mechanical polishing (CMP) method until the first interlayer insulating film 30 is exposed. Thereby, the material remains in the opening, and the remaining material is used for the heater electrode 32.

### [Second Process Step]

FIG. 4 is a diagram illustrating the cross-section of the semiconductor device at a process step for showing the manufacturing method of the semiconductor device in accordance with the first preferred embodiment of the present invention, where the hole 42 is formed.

After forming the heat electrode 32, the second interlayer insulating film 40 is formed to cover the first interlayer insulating film 30. The second interlayer insulating film 40 may be silicon oxide, silicon nitride (Si₃N₄) or the like. The second interlayer insulating film 40 may be about 150 nm in thickness.

Next, photolithograph technique and dry etching technique are performed for forming the hole 42 which penetrates the second interlayer insulating film 40. The hole 42 may be about 100 nm in diameter. In this case, the side surface 42c of the hole 42 is approximately perpendicular to the semiconductor substrate, and the top surface 32a of the heater electrode 32 is exposed corresponding to the bottom 42a of the hole 42.

### [Third Process Step]

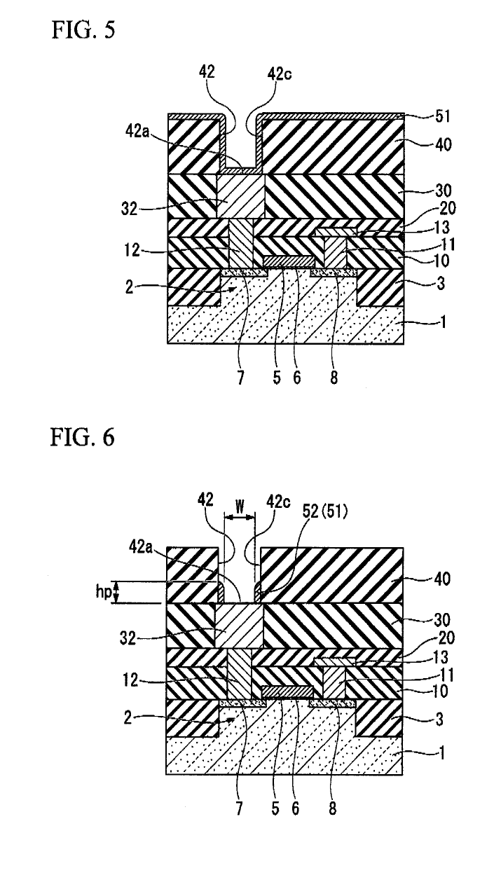

FIG. 5 is a diagram illustrating the cross-section of the semiconductor device at a process step for showing the manufacturing method of the semiconductor device in accordance with the first preferred embodiment of the present invention, where a conductive film 51 is formed.

After forming the hole 42, the conductive film 51 is formed to cover the second interlayer insulating film 40 by use of CVD or the like. The conductive film 51 is formed so as to achieve proper coverage for the side surface 42c and the bottom 42a of the hole 42. In this case, the hole 42 is not entirely filled with the conductive film. The conductive film 51 may be titanium nitride (TiN) or the like. The conductive film 51 may be about 15 nm in thickness. In general, the material of the conductive film 51 is not effectively supplied into the hole 42. Therefore, when the conductive film 51 is formed to be 15 nm thick over the second interlayer insulating film 40, the conductive film 51 is formed to be 10 nm to 15 nm thick on the side surface 42c and the bottom 42a of the hole 42.

FIG. 6 is a diagram illustrating the cross-section of the semiconductor device at a process step for showing the manufacturing method of the semiconductor device in accordance with the first preferred embodiment of the present invention, where the conductive sidewall film 52 is formed.

After the conductive film 51 is formed, the TiN film of the conductive film 51 is selectively etched with dry etching technique using a gas including chlorine, that is, an etch-back process is performed for the conductive film 51 until the top surface 32a of the heater electrode 32 is exposed. As a result, the conductive sidewall film 52 with a ring shape is formed at the side of the heater electrode 32 on the side surface 42c of the hole 42.

The bottom 42a of the hole 42 includes a region which is not covered with the conductive sidewall film 52. The region has the opening diameter (or dimension) W. The opening diameter (or dimension) W is about 70 nm as shown in FIG. 6. The height (or dimension) hp of the conductive sidewall film 52 is formed to be about 50 nm by controlling the etch-back process.

### [Fourth Process Step]

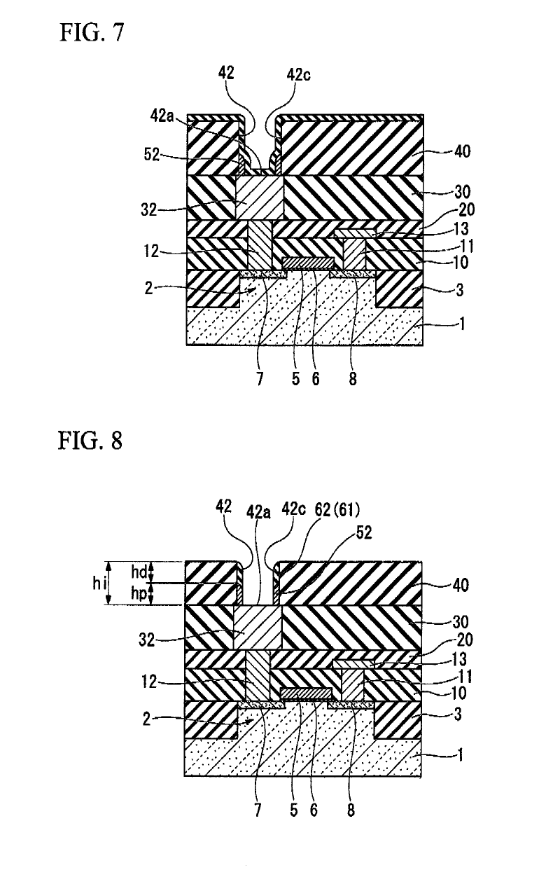

FIG. 7 is a diagram illustrating the cross-section of the semiconductor device at a process step for showing the manufacturing method of the semiconductor device in accordance with the first preferred embodiment of the present invention, where an insulating film 61 is formed.

After forming the conductive sidewall film 52, the insulating film 61 is formed to cover the second interlayer insulating film 40 and the inside of the hole 42 by use of CVD or the like. The insulating film 61 may be silicon nitride, silicon oxide or the like. For example, the insulating film 61 may be about 15 nm in thickness, which is almost the same thickness as that of the conductive film 51. Then, the insulating film 61 can properly cover the side surface 42c and the bottom 42a of the hole 42 and the surface of the conductive sidewall film 52.

FIG. 8 is a diagram illustrating the cross-section of the semiconductor device at a process step for showing the manufacturing method of the semiconductor device in accordance with the first preferred embodiment of the present invention, where the insulating sidewall film 62 is formed.

After the insulating film 61 is formed, the insulating film 61 is etched with dry etching technique using a gas including carbon tetrafluoride (CF₄), that is, the etch-back process is performed for the insulating film 61 until the top surface 32a of the heater electrode 32 is exposed. In this case, the dry etching process is performed with nonselective condition for the second interlayer insulating film 40. As a result, the insulating sidewall film 62 with a ring shape is formed on the side surface 42c of the hole 42 at the upper exposed region of the hole 42 as shown in FIG. 8.

In this case, an over-etching process is performed until the side surface of the conductive sidewall film 52 is fully exposed. With this over-etching process, the top surface of the second interlayer insulating film 40 is removed about 50 nm thick. The height hi (or dimension hi) of the second interlayer insulating film 40 is formed to be about 100 nm. The height hd (or dimension lid) of the insulating sidewall film 62 is formed to be about 50 nm. Finally, the top surface of the insulating sidewall film 62 and the top surface of the second interlayer insulating film 40 are aligned at almost the same level, as shown in FIG. 8.

[Fifth Process Step]

After forming the insulating sidewall film 62, the phase change material film 70 is formed to fill the hole 42 and cover the second interlayer insulating film 40.

The material of the phase change material film 70 with about 60 nm thick may be formed from chalcogenide materials or the like.

### [Sixth Process Step]

The upper electrode 80 is formed to cover the phase change material film 70. The upper electrode 80 may be formed with titanium nitride or the like. The thickness of the upper electrode 80 may be about 50 nm. According to the process steps described above, the semiconductor device of FIG. 1 is manufactured in accordance with the preferred embodiment of the present invention.

The semiconductor device in accordance with the preferred embodiment includes the semiconductor substrate 1, and the following elements. The first interlayer insulating film 30 is formed on the semiconductor substrate 1. The heater electrode 32 is formed in the first interlayer insulating film 30. The second interlayer insulating film 40 is formed over the first interlayer insulating film 30 having the hole 42 which exposes the top surface 32a of the heater electrode 32. The phase change material film 70 is formed to fill the hole 42 and cover the part of the top surface 40a of the second interlayer insulating film 40. The upper electrode 80 is formed to cover the top surface of the phase change material film 70. The conductive sidewall film 52 is formed in the hole 42 contacting the top surface 32a of the heater electrode 32. The conductive sidewall film 52 is located between the second interlayer insulating film 40 and the phase change material film 70. The insulating sidewall film 62 is formed in the hole 42. The insulating sidewall film 62 contacts the top surface 52a of the conductive sidewall film 52. The insulating sidewall film 62 is located between the second interlayer insulating film 40 and the phase change material film 70. This structure enables that the conductive sidewall film 52 heats only the phase change region 70A without decreasing the heating coefficient, so that the phase change memory reduces its operation current.

The semiconductor device in accordance with the preferred embodiment includes, in the hole 42, the conductive sidewall film 52 and the insulating sidewall film 62. The conductive sidewall film 52 and the insulating sidewall film 62 are formed to surround the side surface 70e of the phase change material film 70. The phase change material film 70 includes the region 70A (the phase change region 70A) whose resistance is changed by a heat caused by the heat electrode 32. The region 70A is surrounded by the conductive sidewall film 52. This structure enables that the conductive sidewall film 52 heats only the phase change region 70A without decreasing the heating coefficient, so that the phase change memory reduces its operation current.

The semiconductor device in accordance with the preferred embodiment includes the conductive sidewall film 52 having the height hp (or dimension hp). The height hp is equal to or smaller than 1.2 times of the diameter (or dimension) of the contact area at which the phase change material film 70 contacts the heater electrode 32. This structure enables that the conductive sidewall film 52 heats only the phase change region 70A without decreasing the heating coefficient, so that the phase change memory reduces its operation current,

The semiconductor device in accordance with the preferred embodiment includes the conductive sidewall film 52, which is made of a metal or an alloy having a resistance that is smaller than that of the phase change material film 70 in the amorphous state. This structure enables that the operation current is reduced and the phase change material film 70 is heated up effectively.

The semiconductor device in accordance with the preferred embodiment includes the conductive sidewall film 52, which is formed from W, Ti, Ta, TiN, TaSiN, or TiSiN. This enables that the operation current is reduced and the phase change material film 70 is heated up effectively.

The semiconductor device in accordance with the preferred embodiment includes the heater electrode 32. The heater electrode 32 is electrically coupled to the switching element 9. The switching element 9 is formed on the plane 1a of the semiconductor substrate 1. The switching element 9 is provided with the MOS transistor. This structure enables that the current drive capability (ON current) is reduced for a MOS transistor combined with the phase change element. It is possible to reduce the size of MOS transistors. The phase change memory with higher integration can be manufactured.

The manufacturing method of the semiconductor device in accordance with the preferred embodiment includes the following processes. The heater electrode 32 is formed after the first interlayer insulating film 30 is formed on the semiconductor substrate 1. The heater electrode 32 is formed in the first interlayer insulating film 30. The hole 42 is formed in the second interlayer insulating film 40 to expose the top surface 32a of the heater electrode 32. The conductive sidewall film 52 is formed to cover the lower side surface of the hole 42. The conductive sidewall film 52 is formed after forming the conductive film 51. The conductive film 51 covers the second interlayer insulating film 40 and the inside of the hole 42. The conductive sidewall film 52 is formed by etching back the conductive film 51. The insulating sidewall film 62 is formed after forming the insulating film 61. The insulating film 61 covers the second interlayer insulating film 40 and the surface of the conductive sidewall film 52. The insulating sidewall film 62 is formed to cover the upper inside side surface of the hole 42. The insulating sidewall film 62 is formed by etching back the insulating film 61. The phase change material film 70 is formed to cover the top surface 40a of the second interlayer insulating film 40. The phase change material film 70 is formed to fill the hole 42 through the insulating sidewall film 62 and the conductive sidewall film 52. The upper electrode 80 is formed, which covers the phase change material film 70. These processes enable that the phase change memory with a reduced operation current is easily manufactured without reducing the heating efficiency. Further, it enables that the current drive capability is reduced for MOS transistor combined with the phase change element, and it is possible to reduce the size of MOS transistors, so that the phase change memory with improved integration can be manufactured.

### Second Embodiment

The following will describe the semiconductor device in accordance with a second preferred embodiment of the present invention.

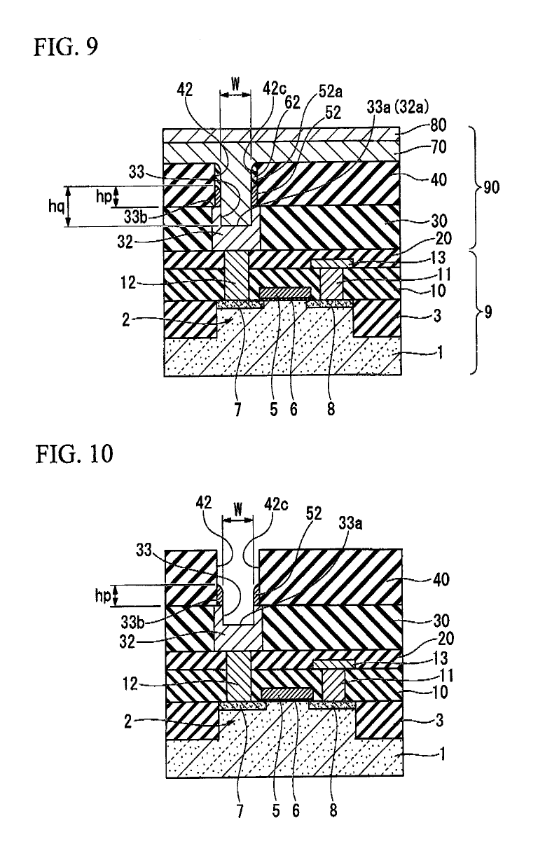

FIG. 9 is a diagram illustrating the cross-section of a semiconductor device in accordance with the second preferred embodiment of the present invention.

The semiconductor device according to the present embodiment includes the heater electrode 32 which includes a trench portion 33 (non-flat surface 33) having a top surface which has a surface level and a bottom surface having a bottom level. Since most parts are identical to those of the semiconductor device described in the first embodiment except that the semiconductor device according to the present embodiment includes the heater electrode 32 having the trench portion 33 where the phase change material film 70 is formed to fill the bottom surface of the trench portion 33. Therefore, the identical parts are used for the same symbols as those used in the first embodiment in the following.

As shown in FIG. 9, the semiconductor device according to the present embodiment is a phase change memory, which includes a memory cell formed of the phase change element 90 and the switching element 9.

The heater electrode 32 includes the trench portion 33 at the side of the phase change material film 70. A width of the trench portion 33 is formed to be the same as the opening diameter W. The phase change material film 70 is formed to fill not only in the hole 42 but in the trench portion 33. The conductive sidewall film 52 is formed to contact the top surface 33b of the trench portion 33.

A height hq indicates a distance between the bottom surface 33a of the trench portion 33 and a top surface 52a of the conductive sidewall film 52. It is preferable that the height hq is formed to be equal to or smaller than 1.2 times of the opening diameter W which corresponds to a diameter of the bottom surface 33a of the trench portion (non-flat surface) 33. In this way, the height hq can be formed to be equal to or less than the height hs of the phase change region 70A, so that only the phase change region 70A can be heated by the conductive sidewall film 52 and the heater electrode 32. This enable that the operation current is reduced without the heating efficiency.

A manufacturing method of the semiconductor device in accordance with the second preferred embodiment will be described below.

FIG. 10 is a diagram illustrating the cross-section of the semiconductor device at a process step for showing the manufacturing method of the semiconductor device in accordance with the second preferred embodiment of the present invention, where the conductive sidewall film 52 and the trench portion 33 are formed. When parts of the present semiconductor device are identical to those used in the first preferred embodiment, the same symbols are used for the parts.

At the process step shown in FIG. 3 of the first preferred embodiment, the heater electrode 32 is formed from tungsten. In the present embodiment, the heater electrode 32 of the present embodiment will be formed from the same material as that of the conductive film 51 of the conductive sidewall film 52. For example, when the conductive film 51 is formed from titanium nitride (TiN), the heater electrode 32 is also formed from TiN.

Another material, which is not TiN, may be used as the material of the heater electrode 32 as long as the resistance of the material for the heater electrode 32 is smaller than that of the phase change material film 70 at amorphous state. In this case, the material of the conductive film 51 is the same as that used for forming the heater electrode 32.

Next, after forming the heater electrode 32, the second interlayer insulating film 40 is formed to cover the first interlayer insulating film 30. The material of the second interlayer insulating film 40 is formed from silicon oxide, silicon nitride (Si₃N₄) or the like.

The hole 42 is formed by photography and dry etching techniques. The hole 42 penetrates the second interlayer insulating film 40 and exposes the top surface 32a of the heater electrode 32.

The conductive film 51 is formed to cover the second interlayer insulating film 40 by use of CVD or the like. The conductive film 51 is formed so as to achieve proper coverage for the side surface 42c and the bottom 42a of the hole 42.

The TiN film of the conductive film 51 is selectively etched with dry etching technique using a gas including chlorine, that is, the etch-back process is performed for the conductive film 51 so that the conductive sidewall film 52 with a ring shape is formed on the side surface 42c of the hole 42 at lower side of the hole 42 as shown in FIG. 10.

As a result, the trench portion 33 having a top surface and a bottom surface is formed at the upper side of the heater electrode 32 as shown in FIG. 9. This is because the material of the heater electrode 32 is the same as that of the conductive film 51, so the top surface 32a of the heater electrode 32 is etched simultaneously while the conductive film 51 is etched.

After forming the conductive sidewall film 52 and the trench portion 33, the insulating film 61 is formed to cover the second interlayer insulating film 40 and the inside of the hole 42 by use of CVD or the like. The insulating film 61 may be silicon nitride, silicon oxide or the like. The insulating film 61 may be almost the same thickness as that of the conductive film 51.

The insulating film 61 is etched with dry etching technique using a gas including carbon tetrafluoride (CF₄), that is, the etch-back process is performed for the insulating film 61 until the bottom surface 33a of the trench portion 33 is exposed so that the insulating sidewall film 62 is formed on the side surface 42c of the hole 42 as shown in FIG. 9.

In this case, the etch-back process is performed until the side surface of the conductive sidewall film 52 is fully exposed. With this etch-back process, which is an over etching process, the top surface of the second interlayer insulating film 40 is also slightly etched.

The phase change material film 70 is formed to fill in the hole 42 and the bottom surface 33a of the trench portion 33 with covering the top surface of the second interlayer insulating film 40. The phase change material film 70 may be chalcogenide materials or the like.

The upper electrode 80 is formed to cover the phase change material film 70. The upper electrode 80 may be titanium nitride or the like.

With the process steps as described above, the semiconductor device of FIG. 9 according to the present embodiment is manufactured.

The semiconductor device in accordance with the preset embodiment includes the heater electrode 32 having the trench portion 33 at its top surface, and the conductive sidewall film 52 formed to contact to the top surface 33b of the trench portion 33. In this case, the height hq indicates the distance between the bottom 33a of the trench portion 33 and the top surface 52a of the conductive sidewall film 52, and the height hq is formed to be equal to or smaller than 1.2 times of the opening diameter W, which corresponds to the diameter of the bottom 33a of the trench portion 33. This enables that the conductive sidewall film 52 heats only the phase change region 70A without decreasing the heating coefficient, so that the phase change memory reduces its operation current.

The semiconductor device according to the present embodiment of the present invention includes the conductive sidewall film 52 whose material is the same as that of the heater electrode 32. This enables that the trench portion 33 of the heater electrode 32 is simply formed at the top surface of the heater electrode 32 by etching the conductive sidewall film 52.

The manufacturing method of the semiconductor device in accordance with the second preferred embodiment of the present invention includes the third process, where the trench portion 33 is formed by etching the heater electrode 32 while etch-back is performed for the conductive film 51 after the conductive film 51 having the same material as that of the heater electrode 32 is formed. This enables that the conductive sidewall film 52 and the heater electrode 32 can heat only the phase change region 70A, and that the phase change memory which the operation current is reduced is easily manufactured without reducing the heating efficiency.

### Third Embodiment

The semiconductor device in accordance with the third preferred embodiment of the present invention is described blow.

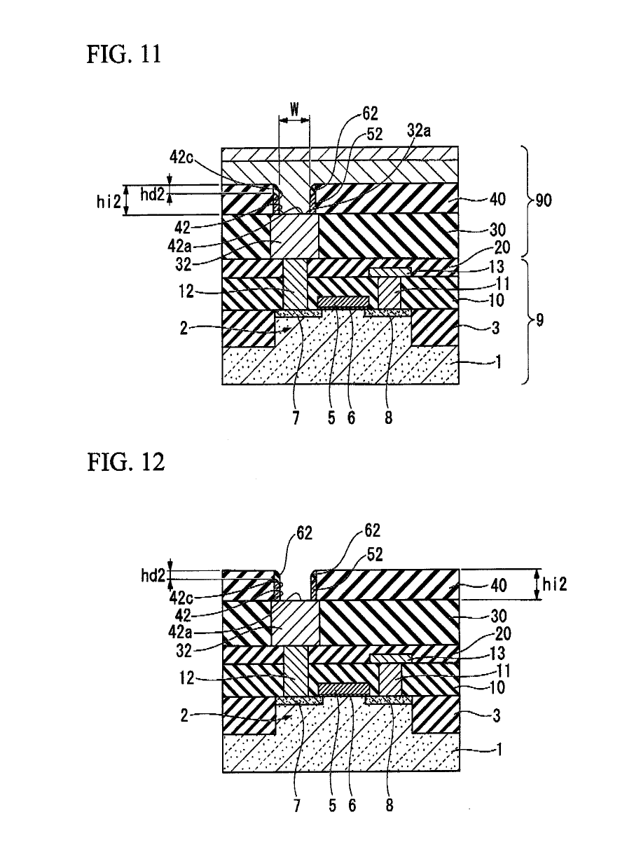

FIG. 11 is a diagram illustrating the configuration of a circuit for a semiconductor device 3 in accordance with a third preferred embodiment of the present invention.

The semiconductor device according to the present embodiment includes parts identical to those used in the first embodiment except that the thickness of the second interlayer insulating film 40 is thinned and the height of the insulating sidewall 62 is reduced. Therefore, when the parts used in the present embodiment are identical to those used in the first embodiment, the identical symbols are used for describing the present embodiment.

As shown in FIG. 11, the semiconductor device according to the present embodiment is a phase change memory which includes a memory cell having the switching element 9 and the phase change element 90 formed on the semiconductor substrate 1.

The height hi2 of the second interlayer insulating film 40 is formed to be about 70 nm, which is smaller than the height hi (about 100 nm) of that used in the first embodiment. The height hd2 of the insulating sidewall 62 of the present embodiment is formed to be about 20 nm, which is smaller than the height hd (about 50 nm) of that used in the first embodiment. Further, the height hp of the conductive sidewall film 52 of the present embodiment is about 50 nm, which is almost the same as the height hp of that used in the first embodiment.

In this way, it is preferable that the second interlayer insulating film 40 is thinned so that the diameter of the hole 42 becomes relatively greater to the depth of the hole 42. Specifically, it is preferable that the depth hi2 of the hole 42 is formed to be equal to or less than the diameter of the hole 42. When the depth hi2 of the hole 42 is formed to be equal to or less than the diameter of the hole 42, the aspect ratio of the depth hi2 of the hole 42 against the width (diameter) of the hole 42 becomes smaller. As a result, the phase change material film 70 can be easily filled in the hole 42. This can reduce the formation of voids of the phase change material film 70 in the hole 42, so that the operation current is reduced without increasing the heating efficiency. Further, it is preferable that the depth hi2 of the hole 42 is equal to or less than the opening diameter W, which corresponds to the diameter of a plane 70c where the heater electrode 32 contacts the phase change material film 70. This can prevent the phase change region 70A from laterally spreading beyond the opening diameter W. When the aspect ratio of the depth hi2 of the hole 42 against the opening diameter W becomes less than unity, the phase change region 70A can be formed to beyond the opening diameter W and spreads toward lateral direction.

The manufacturing method of the semiconductor device according to the third embodiment will be described below.

FIG. 12 is a diagram illustrating the cross-section of the semiconductor device of FIG. 11 at a process step for showing the manufacturing method of the semiconductor device in accordance with the third preferred embodiment of the present invention, where the insulating sidewall 62 is formed. When the parts used in following description are identical to those used in the first embodiment, the identical parts will be indicated by the identical symbols which are used in the first embodiment.

In the first step, the heater electrode 32 is formed by use of the similar process used in the first embodiment, and then the second interlayer insulating film 40 is formed to cover the first interlayer insulating film 30. The second interlayer insulating film 40 may be made of silicon oxide, silicon nitride (Si₃N₄) or the like. A film thickness hit of the second interlayer insulating film 40 may be, for example, about 150 nm.

A hole 42 is formed, which penetrates the second interlayer insulating film 40 so as to expose the top surface 32a of the heater electrode 32. The diameter of the hole 42 may be about 100 nm.

The conductive film 51 is formed to cover the second interlayer insulating film 40 by use of CVD or the like. The conductive film 51 is formed so as to achieve proper coverage for the side surface 42c and the bottom 42a of the hole 42. The conductive film 51 may be titanium nitride (TiN) or the like. The conductive film 51 may be about 15 nm in thickness.

Next, the TiN film of the conductive film 51 is selectively etched with dry etching technique using a gas including chlorine, that is, an etch-back process is performed for the conductive film 51 until the top surface 32a of the heater electrode 32 is exposed. As a result, the conductive sidewall film 52 with a ring shape is formed at lower side of the hole 42 on the side surface 42c of the hole 42 as shown in FIG. 12.

The insulating film 61 is formed to cover the second interlayer insulating film 40 and the inside of the hole 42 by use of CVD or the like. The insulating film 61 may be silicon nitride, silicon oxide or the like. The insulating film 61 may be about 15 nm.

The insulating film 61 is etched with dry etching technique using a gas including carbon tetrafluoride (CF₄), that is, the etch-back process is performed for the insulating film 61 until the top surface 32a of the heater electrode 32 is exposed so that the insulating sidewall film 62 is formed on the side surface 42c of the hole 42 as shown in FIG. 12.

In this case, the etch-back process is performed for over etching until the side surface of the conductive sidewall film 52 is fully exposed. With this etch-back process, the top surface of the second interlayer insulating film 40 is also etched about 50 nm. As a result, the second interlayer insulating film 40 becomes about 100 nm in thickness and the height hd2 of the insulating sidewall film 62 becomes about 50 nm.

Further, the second interlayer insulating film 40 is removed by Chemical Mechanical Polishing (CMP) method so that the height hit of the second interlayer insulating film 40 becomes about 70 nm. At this stage, the height hd2 of the insulating sidewall film 62 becomes about 20 nm.

After forming the insulating sidewall film 62, the phase change material film 70 is formed about 60 nm to fill in the hole 42 with covering the top surface of the second interlayer insulating film 40. The phase change material film 70 may be chalcogenide materials or the like.

The upper electrode 80 is formed about 50 rim to cover the phase change material film 70. The upper electrode 80 may be titanium nitride or the like.

With the process steps as described above, the semiconductor device of FIG. 11 according to the present embodiment is manufactured.

The semiconductor device according to the preset embodiment includes the hole 42 which is formed to have the diameter being equal to or greater than its depth. Thus, when the aspect ratio of the hole 42 is reduced, it can prevent the phase change material film 70 from the void formation in the hole 42. This enables that the operation current is reduced without decreasing the heating efficient.

The semiconductor device according to the preset embodiment includes the step of polishing the second interlayer insulating film 40 by CMP method for thinning the second interlayer insulating film 40 after the fourth process step and before the fifth process step. This enables that the depth hit of the hole 42 is smaller than one time of the width (diameter) of the hole 42. Further it is simply possible that the depth h12 of the hole 42 is formed to be equal to or greater than one time of the diameter of the plane 70c where the phase change material film 70 contacts the heater electrode 32. This makes it possible that the operation current is reduced without decreasing the heating efficiency, and that it prevents the phase change material film 70 from laterally spreading beyond the opening diameter W.

The present invention relates to a semiconductor device and the method for manufacturing the semiconductor device. More specifically, the present invention relates to the semiconductor device including a phase change memory that can reduce the operation current without decreasing the heating efficiency and to the manufacturing method thereof. The present invention can be applied to the industry which uses the semiconductor device and manufacturers the semiconductor device.

According to a device structure mentioned above, only the phase change region can be heated without reducing the heating efficiency of a phase change material, so that it is possible to provide a semiconductor device and a manufacturing method thereof capable of reducing the operation current.

Further, the present invention can be applied to most semiconductor apparatuses, such as CPU (Central Processing Unit), MCU (Micro Control Unit), DSP (Digital Signal Processor), ASIC (Application Specific Standard Circuit), DRAM (Dynamic Random Access Memory), SRAM (Static Random Access Memory), non-volatile memories, for example, flush memories, or the like.

A semiconductor device and a method of manufacturing the semiconductor device according to the present invention are applicable to a semiconductor device including a vertical device including a pillar connected to a contact plug, and a method of manufacturing the same.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a first insulating film over a semiconductor substrate, the first insulating film having a first opening;
a first electrode in the first opening;
a second insulating film on the first insulating film, the second insulating film having a second opening that exposes a top surface of the first electrode;
a first conductive film in the second opening, the first conductive film being connected to the first electrode, the first conductive film having a top surface that is lower than a top surface of the second insulating film; and
a phase change material film in the second opening, the phase change material film comprising first and second portions in the second opening, the first portion being disposed on the top surface of the first electrode and a side surface of the first conductive film.

2. The semiconductor device according to claim 1, wherein the first portion of the phase change material film is located under the second portion of the phase change material film in the second opening.

3. The semiconductor device according to claim 2, wherein the first conductive film comprises:
a conductive sidewall on a side surface of the second opening, the conductive sidewall surrounding the first portion of the phase change material film.

4. The semiconductor device according to claim 3, further comprising:
an insulating sidewall on the side surface of the second opening, the insulating sidewall being positioned on a top surface of the conductive sidewall.

5. The semiconductor device according to claim 4, wherein the phase change material film further comprises:
a layered portion that extends on the second insulating film; the second portion being disposed between the layered portion and the first portion of the phase change material film.

6. The semiconductor device according to claim 5, further comprising:
a second electrode being disposed on a top surface of the layered portion of the phase change material film.

7. The semiconductor device according to claim 5, wherein the second portion is surrounded by the insulating sidewall, the first portion includes a phase change region to vary in resistance by a heat generated by the first electrode.

8. The semiconductor device according to claim 5, wherein the first portion has a first dimension in a first direction vertical to a side surface of the insulating sidewall, the first portion has a second dimension in a second direction parallel to the side surface of the insulating sidewall, the first dimension is equal to or less than 1.2 times of the second dimension.

9. The semiconductor device according to claim 1, wherein the second opening has a third dimension in the second direction and a fourth dimension in the first direction, the third dimension is equal to or greater than the fourth dimension.

10. The semiconductor device according to claim 1, wherein a material of the first electrode comprises the same material as that of the first conductive film.

11. The semiconductor device according to claim 1, wherein the first conductive film comprises at least one of a metal or an alloy which are lower in resistivity than the phase change material film in amorphous state.

12. The semiconductor device according to claim 1, wherein the first conductive film comprises at least one of tungsten, titanium, tantalum, titanium nitride, tantalum silicide nitride and titanium silicide nitride.

13. The semiconductor device according to claim 1, further comprising:
a switching element coupled to the first electrode.

14. A semiconductor device comprising:
an insulating film having an opening;
a conductive layer in the opening, the conductive layer having a trench portion, the trench portion having a top surface that is lower than a top surface of the insulating film; and
a phase change material film in the opening, the phase change material film comprising first and second portions, the first portion contacting the top surface of the trench portion of the conductive layer, the first portion being surrounded by a side surface of the trench portion.

15. The semiconductor device according to claim 14, wherein the conductive layer comprises:
an electrode film in a lower portion of the opening; and
a conductive sidewall on a side surface of the opening, the conductive sidewall being disposed on an upper surface of the electrode film,
wherein the trench portion comprises the conductive sidewall and the upper surface of the electrode film, and
the first portion of the phase change material film is surrounded by the conductive sidewall.

16. The semiconductor device according to claim 15, wherein the first portion of the phase change material film has a first dimension in a first direction parallel to an upper surface of the insulating film, and the first dimension is equal to or less than 1.2 times of a second dimension of the first portion, the second dimension being defined in a second direction vertical to the first direction.

17. The semiconductor device according to claim 15, further comprising:
an insulating sidewall on the side surface of the opening, the insulating sidewall being positioned over the conductive sidewall, and the insulating sidewall surrounding the second portion of the phase change material film.
